(19) United States
(12) Patent Application Publication
(10) Pub. No.: US 2025/0089391 A1
(43) Pub. Date: Mar. 13, 2025

(54) IMAGE CAPTURING APPARATUS AND ELECTRONIC EQUIPMENT

(71) Applicant: SONY SEMICONDUCTOR SOLUTIONS CORPORATION, KANAGAWA (JP)

(72) Inventor: SAYAKA TAKAI, KANAGAWA (JP)

(21) Appl. No.: 18/292,717

(22) PCT Filed: Jul. 26, 2022
(86) PCT No.: PCT/JP2022/028684

§ 371 Date: Jan. 26, 2024

(30) Foreign Application Priority Data
Aug. 6, 2021 (JP) 2021-130160

(51) Int. Cl. H01L 27/146

(52) U.S. Cl. CPC H10F 39/806; H10F 39/184; H10F 39/8057; H10F 39/8063

(57) ABSTRACT

[Object]

To provide an image capturing apparatus and electronic equipment that can suppress occurrence of a flare.

[Solving Means]

An image capturing apparatus includes a photoelectric conversion region having a photoelectric conversion portion for each pixel, and a light controlling region laminated on the photoelectric conversion region and configured to convert an optical characteristic incident thereon. The light controlling region has a plurality of unit structural bodies, and each of the plurality of unit structural bodies has a plurality of meta structural bodies. The plurality of meta structural bodies include two or more meta structural bodies whose optical characteristics are different from each other.

### TECHNICAL FIELD

The present disclosure relates to an image capturing apparatus and electronic equipment.

### BACKGROUND ART

In a security camera or the like, it is typical to use a sensor for photoelectrically converting IR (Infrared Ray) light (such sensor is hereinafter referred to as an IR light sensor) (refer to PTL 1). Since the IR light has a wavelength longer than that of visible light and is less likely to be scattered, it is also possible to capture an image of an internal state of an object. Further, the IR light sensor can perform not only image capturing of a temperature variation of an object that cannot be recognized by the human eye but also image capturing in a dark environment.

### CITATION LIST

### Patent Literature

[PTL 1]
Japanese Patent Laid-open No. 2019-175912

### SUMMARY

### Technical Problem

However, in a case where there is a high-luminance light source in an angle of view with which image capturing is performed by the IR light sensor, a petal-like flare sometimes occurs. A light incidence face of the IR light sensor has a periodic structure including a plurality of pixels. Accordingly, if intense light enters the light incidence face of the IR light sensor, then diffraction reflection occurs, and the diffraction light is reflected again by cover glass and enters the sensor, whereupon such a petal-like flare as described above occurs. Since a flare of the type just described causes deterioration of image quality of the captured image, a countermeasure is required.

Therefore, the present disclosure provides an image capturing apparatus and electronic equipment that can suppress occurrence of a flare.

### Solution to Problem

In order to solve the problem described above, according to the present disclosure, there is provided an image capturing apparatus including a photoelectric conversion region having a photoelectric conversion portion for each pixel, and a light controlling region laminated on the photoelectric conversion region and configured to convert an optical characteristic of light incident thereon, in which the light controlling region has a plurality of unit structural bodies, each of the plurality of unit structural bodies has a plurality of meta structural bodies, and, the plurality of meta structural bodies include two or more meta structural bodies whose optical characteristics are different from each other.

The light controlling region may increase the optical path length of IR (Infrared Ray) light incident thereon.

Each of the plurality of meta structural bodies may be provided in a corresponding relation with a pixel.

The plurality of unit structural bodies may have the same structure, and each of the plurality of unit structural bodies may have the meta structural bodies arranged in plural number in each of two-dimensional directions.

Each of the plurality of meta structural bodies in the unit structural body may include a plurality of types of microstructural bodies that are different from each other in at least one of width, size, and shape, and each of the plurality of meta structural bodies may convert an optical characteristic of light incident on a corresponding one of the microstructural bodies according to at least one of the width, size, and shape of the plurality of types of microstructural bodies.

The unit structural body may have two or more of the meta structural bodies arranged in a first direction and two or more of the meta structural bodies arranged in a second direction intersecting with the first direction, two of the meta structural bodies that are adjacent to each other in the first direction may be different from each other in orientation of the microstructural bodies, and two of the meta structural bodies that are adjacent to each other in the second direction may be different from each other in orientation of the microstructural bodies.

The plurality of meta structural bodies in the unit structural body may have the microstructural bodies that are different from each other in orientation.

The plurality of meta structural bodies in the unit structural body may have the microstructural bodies that are different in orientation by 90 degrees from each other, and the plurality of unit structural bodies may have two of the meta structural bodies arranged adjacent to each other in the first direction and two of the meta structural bodies arranged adjacent to each other in the second direction.

Each of the plurality of meta structural bodies in the unit structural body may have the plurality of types of the microstructural bodies having circular transverse sections having diameters different from each other.

Two of the meta structural bodies that are arranged in a diagonal direction among the plurality of meta structural bodies in the unit structural body may have the microstructural bodies in the same orientation, and the plurality of unit structural bodies may have two of the meta structural bodies that are arranged adjacent to each other in the first direction but are different in orientation from each other, and two of the meta structural bodies that are arranged adjacent to each other in the second direction but are different in orientation from each other.

Each of the plurality of unit structural bodies may include n×n (n is any integer equal to or greater than 2) of the meta structural bodies arranged n by n in two-dimensional directions, and the light controlling region may have a periodic structure having a period equal to the size of the n meta structural bodies.

The light controlling region may generate diffraction light according to the periodic structure from incident light and allow the diffraction light to propagate inside thereof.

The light controlling region may adjust the plurality of unit structural bodies such that an incidence range of the diffraction light is included in an incidence range of light from a light source that is to enter the photoelectric conversion region.

The image capturing apparatus may further include a light transmission member arranged on the light incidence side with respect to the photoelectric conversion region and configured to re-reflect light reflected by the photoelectric conversion region, and
the unit structural body may satisfy, where the period of the unit structural body is d, the wavelength of the incidence light is A, the distance from the light transmission member to the photoelectric conversion region is h, and the range of light from the light source is x, the expression (1):

$$\begin{matrix}[ Math . 1 ] & \\ d > \frac{λ}{sin ( {tan}^{- 1} ( \frac{x}{2 h} ) )} & ( 1 )\end{matrix}$$

The light transmission member may have an on-chip lens array that condenses incident light.

The light controlling region may be arranged on the face side opposite to the light incidence face of the photoelectric conversion region, and diffract light transmitted through the photoelectric conversion region and incident on the light controlling region, to allow the diffraction light to propagate in the photoelectric conversion region.

The image capturing apparatus may further include a scattering member arranged along the light incidence face of the photoelectric conversion region, and the scattering member may scatter the light diffracted by the light controlling region and propagating in the photoelectric conversion region.

The light controlling region may be arranged on the light incidence face side of the photoelectric conversion region and configured to increase an optical path length of the incident light by the plurality of unit structural bodies in the light controlling region and allow the incident light to propagate along the optical path in the photoelectric conversion region.

The light controlling region may have a first light controlling region arranged on the light incidence face side of the photoelectric conversion region, and a second light controlling region arranged on the face side opposite to the light incidence face of the photoelectric conversion region, and the first light controlling region and the second light controlling region may diffract light propagating in the photoelectric conversion region and incident thereon and allow the diffracted light to propagate in the photoelectric conversion region.

According to the present disclosure, there is provided electronic equipment including an image capturing apparatus that outputs a pixel signal that is imaged, and a signal processing section that performs signal processing for the pixel signal, in which the image capturing apparatus includes a photoelectric conversion region having a photoelectric conversion portion for each pixel, and a light controlling region laminated on the photoelectric conversion region and configured to convert an optical characteristic of light incident thereon, the light controlling region is arranged along a light incidence face and has a plurality of unit structural bodies, and each of the plurality of unit structural bodies has a plurality of meta structural bodies whose optical characteristics are different from each other.

### BRIEF DESCRIPTION OF DRAWINGS

FIG. 1 is a view schematically depicting a state in which a flare is reflected in a captured image captured by an image capturing apparatus.

FIG. 2A is a view depicting a wavefront of diffraction light in a case where the pixel pitch of a sensor is small.

FIG. 2B is a view depicting a wavefront of diffraction light in a case where the pixel pitch of the sensor is large.

FIG. 3 is a block diagram depicting a general configuration of an image capturing apparatus according to an embodiment of the present disclosure.

FIG. 4 is a view illustrating a principle of a microstructural body.

FIG. 5 is a cross sectional view of the image capturing apparatus according to the present disclosure in a lamination direction.

FIG. 6 is a transverse cross sectional view taken along line A-A of FIG. 5.

FIG. 7 is a view depicting a positional relation between a photoelectric conversion region and cover glass.

FIG. 8 is a view depicting an image capturing range of high-luminance light source light.

FIG. 9 is a cross sectional view of an image capturing apparatus according to a first modification to that of FIG. 5 in a lamination direction.

FIG. 10 is a cross sectional view of an image capturing apparatus according to a second modification to that of FIG. 5 in a lamination direction.

FIG. 11A is a transverse sectional view of a unit structural body having a shape different from that in FIG. 6.

FIG. 11B is a transverse sectional view of a unit structural body having a shape different from those in FIGS. 6 and 11A.

FIG. 11C is a transverse sectional view of a unit structural body having a shape different from those in FIGS. 6, 11A, and 11B.

FIG. 12 is a block diagram depicting an example of schematic configuration of a vehicle control system.

FIG. 13 is a diagram of assistance in explaining an example of installation positions of an outside-vehicle information detecting section and an imaging section.

### DESCRIPTION OF EMBODIMENTS

In the following, an embodiment of an image capturing apparatus and electronic equipment is described with reference to the drawings. Although the following description is given focusing on main constituent elements of an image capturing apparatus and electronic equipment, the image capturing apparatus and the electronic equipment possibly have constituent elements or functions that are not depicted or described. The following description does not exclude such constituent elements or functions that are not depicted or described.

### (Principle of Occurrence of Flare)

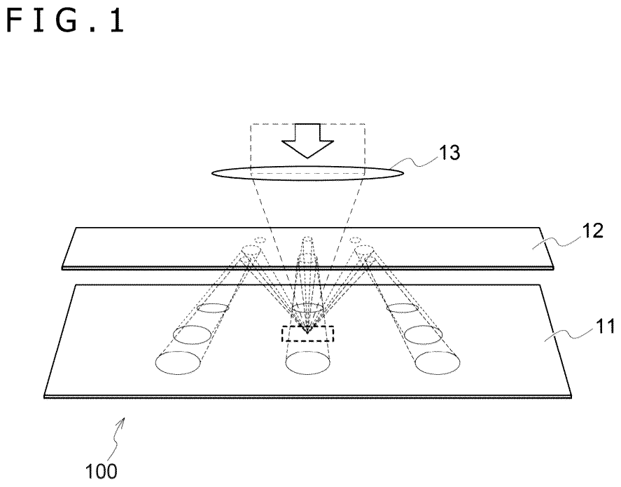

FIG. 1 is a view schematically depicting a state in which a flare is reflected in a captured image taken by an image capturing apparatus 100. As depicted in FIG. 1, the image capturing apparatus 100 includes an image capturing sensor 11 and cover glass 12, and a module lens 13 is arranged forwardly on an optical axis of the image capturing apparatus 100. Image capturing object light transmitted through the module lens 13 is transmitted through the cover glass 12 and enters a light incidence face of the sensor 11. The light incidence face of the sensor 11 has a periodic structure in which a plurality of images are arranged two-dimensionally. Thus, in a case where the image capturing object light includes intense light of a high luminance light source, it is diffracted and reflected by the light incidence face. The diffracted and reflected light (hereinafter referred to as diffraction light) is scattered by the cover glass 12 and enters the light incidence face of the sensor 11 from various directions. Therefore, in the captured image taken by the sensor 11, a petal-like flare is reflected.

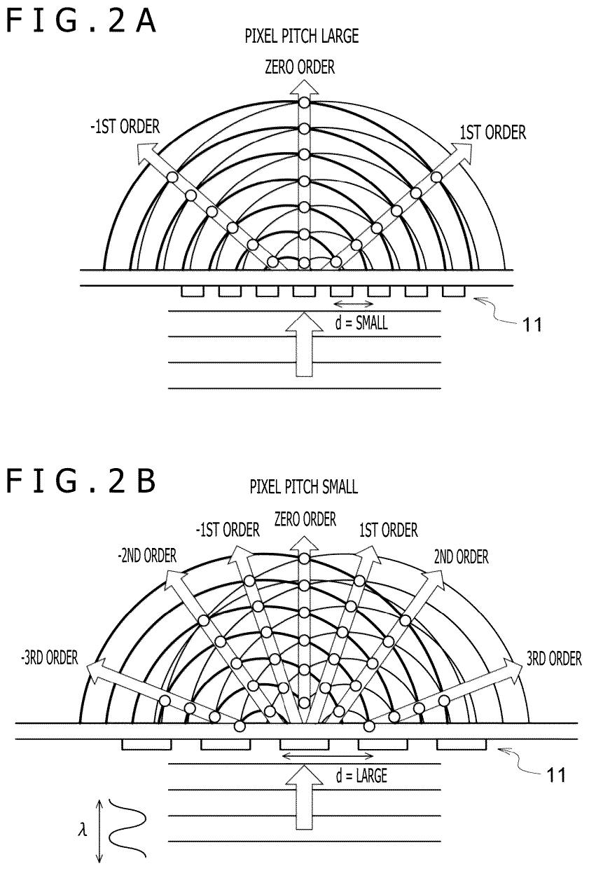

FIGS. 2A and 2B are views each schematically depicting a wavefront of diffraction light, and FIG. 2A depicts a wavefront in a case where the pixel pitch of the sensor 11 is small while FIG. 2B depicts a wavefront in a case where the pixel pitch of the sensor 11 is large. As the pixel pitch of the sensor 11 decreases, the diffraction order number decreases. Further, as the pixel pitch of the sensor 11 decreases, the order number of diffraction light decreases and low order diffraction light travels in a direction of an angle more inclined from a normal direction to the light incidence face. Typically, since low order diffraction light has an intensity higher than that of high order diffraction light, as the pixel pitch decreases, a flare occurs with an increasing intensity.

On the other hand, in a case where the pixel pitch of the sensor 11 is large, although the order number of diffraction light increases as depicted in FIG. 2B, the light intensity of individual rays of diffraction light decreases. Further, rays of low order diffraction light travel in directions of angles near to the normal direction to the light incidence face. Since an image of rays of diffraction light traveling in directions near to the normal direction to the light incidence face is captured in an overlapping relation with light source light, the flare can be suppressed.

In the image capturing apparatus 1 according to the present disclosure, microstructural bodies are arranged on the light incidence face side of a sensor or on the opposite face side to cause a large number of rays of diffraction light to be generated and the intensity of the individual rays of diffraction light to be decreased and to also cause rays of low order diffraction light to travel in directions nearer to the normal line direction to the light incidence face and thereby allow the light source light and the diffraction light to be captured in an overlapping relation with each other and suppress the flare.

### (General Configuration of Image Capturing Apparatus)

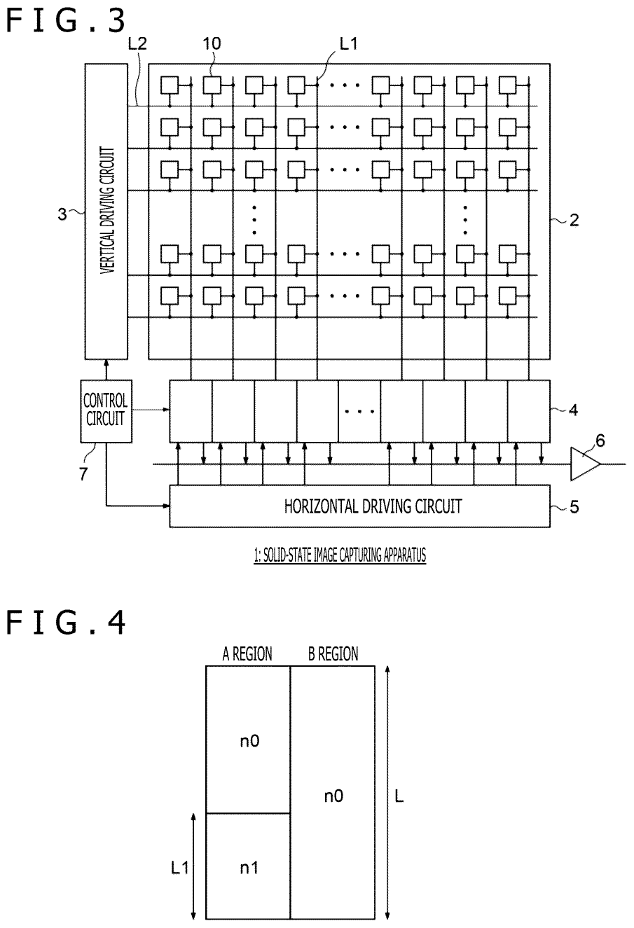

FIG. 3 is a block diagram depicting a general configuration of the image capturing apparatus 1 according to an embodiment of the present disclosure. Although the image capturing apparatus 1 of FIG. 3 presupposes image capturing of incident light in the IR optical band, it may otherwise capture an image additionally in a visible wavelength band.

The image capturing apparatus 1 of FIG. 3 includes a pixel array section 2, a vertical driving circuit 3, a column signal processing circuit 4, a horizontal driving circuit 5, an outputting circuit 6, and a control circuit 7.

The pixel array section 2 includes a plurality of pixels 10 arranged in a row (row) direction and a column (column) direction, a plurality of signal lines L1 extending in the column direction, and a plurality of row selection lines L2 extending in the row direction. Though not depicted in FIG. 3, each pixel 10 has a photoelectric conversion portion and a readout circuit that reads out a pixel signal according to a charge generated by photoelectric conversion to a signal line L1. The pixel array section 2 is a laminated body in which a photoelectric conversion region in which photoelectric conversion portions are arranged in two-dimensional directions and a readout circuit region in which readout circuits are arranged in two-dimensional directions are laminated.

The vertical driving circuit 3 drives the plurality of row selection lines L2. In particular, the vertical driving circuit 3 line-sequentially supplies a driving signal to the plurality of row selection lines L2 to line-sequentially select the row selection lines L2.

To the column signal processing circuit 4, the plurality of signal lines L1 extending in the column direction are connected. The column signal processing circuit 4 performs analog to digital (AD) conversion of a plurality of pixel signals supplied thereto through the plurality of signal lines L1. More particularly, the column signal processing circuit 4 compares a pixel signal on each signal line L1 with a reference signal and generates a digital pixel signal according to a period of time until the signal levels of the pixel signal and the reference signal become the same. The column signal processing circuit 4 sequentially generates a digital pixel signal (P-phase signal) of a reset level of a floating diffusion layer in the pixel and a digital pixel signal (D-phase signal) of a pixel signal level to perform correlated double sampling (CDS: Correlated Double Sampling).

The horizontal driving circuit 5 controls the timing at which an output signal of the column signal processing circuit 4 is to be transferred to the outputting circuit 6.

The control circuit 7 controls the vertical driving circuit 3, the column signal processing circuit 4, and the horizontal driving circuit 5. The control circuit 7 generates a reference signal that is used by the column signal processing circuit 4 to perform AD conversion.

The image capturing apparatus 1 in FIG. 3 is configured by laminating a first board on which the pixel array section 2 and so forth are arranged and a second board on which the vertical driving circuit 3, column signal processing circuit 4, horizontal driving circuit 5, outputting circuit 6, control circuit 7, and so forth are arranged on each other with use of Cu—Cu connection, bumps, vias, or the like.

A photodiode PD of each pixel in the pixel array section 2 is arranged in the photoelectric conversion region. Though not depicted in FIG. 3, the image capturing apparatus according to the present embodiment includes a light controlling region laminated on the photoelectric conversion region. The light controlling region uses a microstructural body to convert an optical characteristic of incident light as hereinafter described. More particularly, the light controlling region increases the optical path length for incident light (IR light) to improve the quantum efficiency Qe of the photoelectric conversion region.

FIG. 4 is a view illustrating a principle of a microstructural body 14. FIG. 4 indicates an example in which an A region and a B region that individually transmit light therethrough are arranged adjacent to each other. The A region and the B region have a length L in the propagation direction of light. The B region has a refractive index n0. In contrast, the A region has the refractive index n0 at part (L−L1) thereof and has a refractive index n1 at the remaining part L1 thereof.

An optical path length dA of the A region and an optical path length DB of the B region in FIG. 4 are represented by the following expressions (2) and (3), respectively.

$$dA = n 0 \times ( L - L 1 ) + n 1 \times L 1 \qquad ( 2 )$$

$$dB = n 0 \times L \qquad ( 3 )$$

Thus, an optical path length difference Δd between the A region and the B region is represented by the following expression (4).

$$Δ d = d B - dA = L 1 ( n 0 - n 1 ) \qquad ( 4 )$$

Meanwhile, a phase difference φ between the A region and the B region is represented by the following expression (5).

$$φ = 2 Π L 1 ( n 0 - n 1 ) / λ \qquad ( 5 )$$

As indicated by the expression (5), rays of light propagating in the A region and the B region are different in optical path length according to a difference in refractive index between the A region and the B region and besides are different in propagation direction according to the difference in refractive index. The difference in propagation direction depends upon the wavelengths of the rays of light.

In such a manner, by introducing light into the microstructural body 14, the optical path length and the propagation direction of the light can be changed. Further, by adjusting the width, shape, direction, or number of the microstructural body 14, the optical path length and the propagation direction of light can be changed variously.

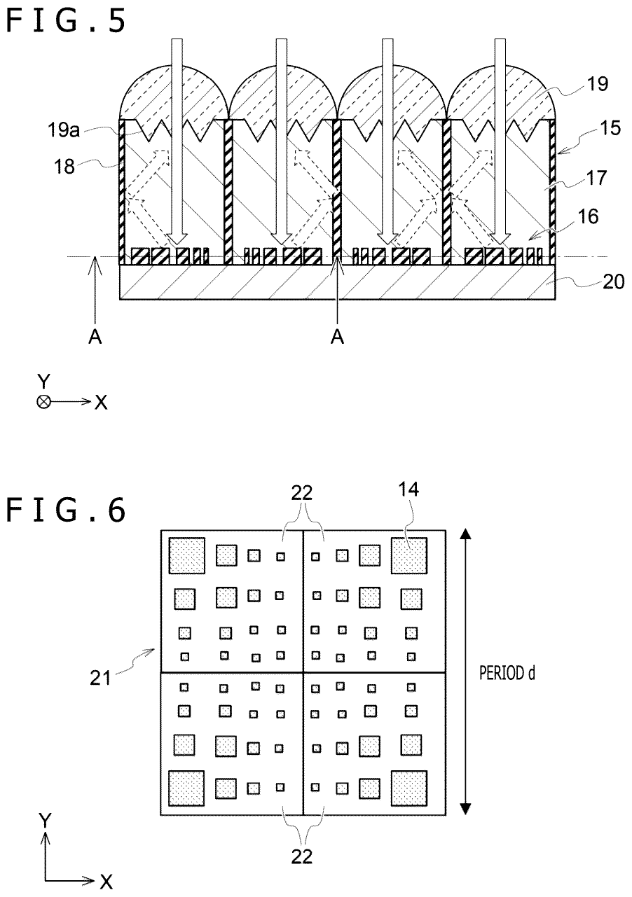

FIG. 5 is a cross sectional view of the image capturing apparatus 1 according to the present disclosure in the lamination direction, and FIG. 6 is a transverse sectional view taken along line A-A of FIG. 5. While FIG. 5 depicts a cross sectional view of four pixels in the X direction, FIG. 6 depicts a cross sectional view of 2 pixels in both the X direction and the Y direction.

As depicted in FIG. 5, the image capturing apparatus 1 includes a photoelectric conversion region 15 and a light controlling region 16.

The photoelectric conversion region 15 has a photoelectric conversion portion 17 for each pixel. In a boundary region of a pixel, a light shielding member 18 is arranged. The light shielding member 18 includes a metal material or an insulating material that reflects or absorbs light. The photoelectric conversion portion 17 performs photoelectric conversion, for example, of IR light. It is to be noted that it is sufficient if the optical wavelength range within which the photoelectric conversion portion 17 can perform photoelectric conversion includes at least the wavelength range of IR light, and the photoelectric conversion portion 17 may perform photoelectric conversion of light in some other wavelength range. On the opposite side of the light controlling region 16 with respect to the photoelectric conversion region 15, a wiring region 20 is arranged. In the wiring region 20, readout circuits for the pixels and so forth are formed.

The light controlling region 16 is laminated on the photoelectric conversion region 15 and converts an optical characteristic of light incident thereon. In particular, the light controlling region 16 can increase the optical path length of incident light and change the traveling direction of the light. Although, in FIG. 5, the light controlling region 16 is arranged on the face side opposite to the light incidence face of the photoelectric conversion region 15, it is also possible to arrange the light controlling region 16 on the light incidence face side of the photoelectric conversion region 15 as hereinafter described.

The light controlling region 16 of FIG. 5 diffracts and reflects light transmitted through the photoelectric conversion region 15, in a direction inclined from the normal direction to the light incidence face of the light controlling region 16. The light controlling region 16 performs an action of decreasing the light intensity of diffraction light while increasing the order number of diffraction light as hereinafter described. This makes it possible to suppress the flare by diffraction light.

As depicted in FIG. 6, the light controlling region 16 has a plurality of unit structural bodies 21, for example, of the same structure arranged along the light incidence face of the light controlling region 16. Although one unit structural body 21 is depicted in FIG. 6, a plurality of such unit structural bodies 21 as depicted in FIG. 6 are arranged in two-dimensional directions. The unit structural body 21 has a size corresponding to a plurality of pixels. FIG. 6 depicts an example in which the unit structural body 21 has a size corresponding to 2×2 pixels.

In the light controlling region 16, a plurality of unit structural bodies 21 of a structure same as that in FIG. 6 are arranged in two-dimensional directions. Consequently, the light incidence face of the light controlling region 16 has a periodic structure having one period equal to the size of the unit structural body 21. The unit structural body 21 has a size of two or more pixels.

If light enters the light incidence face of the light controlling region 16, then diffraction light according to the periodic structure of the light incidence face is generated. Since the unit structural body 21 has a size of two or more pixels, the light incidence face of the light controlling region 16 has a periodic structure of the size of two pixels or more. As the period of the periodic structure of the light controlling region 16 becomes long, the order number of diffraction light diffracted by the light incidence face of the light controlling region 16 increases, while the light intensity of the diffraction light decreases, and low order diffraction light approaches the normal direction to the light incidence face. Therefore, the flare can be suppressed by increasing the period of the periodic structure of the light controlling region 16.

As depicted in FIG. 6, each of the plurality of unit structural bodies 21 in the light controlling region 16 has a plurality of meta structural bodies 22 having optical characteristics different from each other. FIG. 6 depicts an example in which the unit structural body 21 has four meta structural bodies 22. Each of the four meta structural bodies 22 depicted in FIG. 6 is provided in a corresponding relation with a pixel. The unit structural body 21 of FIG. 6 includes two meta structural bodies 22 arranged adjacent to each other in the X direction and two meta structural bodies 22 arranged adjacent to each other in the Y direction.

It is to be noted that FIG. 6 merely depicts an example of the unit structural body 21, and various modifications are available in regard to the number, size, and shape of the plurality of meta structural bodies 22 configuring the unit structural body 21.

Each of the meta structural bodies 22 includes a plurality of types of microstructural bodies 14 that are different in at least one of the width, size, and shape from each other. In the example of FIG. 6, each of the meta structural bodies 22 includes a plurality of microstructural bodies 14 having square shapes that are different from each other in size. The microstructural bodies 14 included in the individual meta structural bodies 22 have optical characteristics different from each other for each type in size, shape, or the like and individually convert light incident thereon into light of an optical wavelength according to a type of a shape, a size, or the like of the microstructural body 14. Consequently, the optical characteristic of each meta structural body 22 depends upon the optical characteristic of the plurality of microstructural bodies 14 in the meta structural body 22.

The unit structural body 21 of FIG. 6 has four meta structural bodies 22 in which the orientations of the plurality of microstructural bodies 14 are different from each other by 90 degrees. Consequently, the four meta structural bodies 22 have optical characteristics different from each other, and the light controlling region 16 has a periodic structure having one period equal to the size of the unit structural body 21.

Hence, in a case where the light controlling region 16 is arranged on the face side opposite to the light incidence face of the photoelectric conversion region 15 as depicted in FIG. 5, when light transmitted through the photoelectric conversion region 15 enters the light controlling region 16, the light controlling region 16 generates diffraction light according to the periodic structure from the incident light and allows the generated diffraction light to propagate in the photoelectric conversion region 15.

Since the periodic structure of the light controlling region 16 is greater than one pixel size as depicted in FIG. 6, the light intensity of diffraction light generated by the light incidence face of the light controlling region 16 becomes lower than the light intensity of diffraction light generated by the light incidence face of the photoelectric conversion region 15, and the order number of diffraction light increases. Although high order number diffraction light has a large inclination angle with respect to the light incidence face as depicted in FIG. 2B, since the intensity of it is lower than that of low order number diffraction light, the flare can be suppressed. On the other hand, since low order number diffraction light travels in a direction near to the normal direction to the light intensity face, it possibly becomes a cause of a flare. However, since the light controlling region 16 in the present embodiment has a periodic structure of two or more pixels, the flare can be suppressed by containing low order number diffraction light having high intensity within the light source.

In a case where the light controlling region 16 is arranged on the face side opposite to the light incidence face of the photoelectric conversion region 15 as depicted in FIG. 5, diffraction light diffracted by the light controlling region 16 propagates in the photoelectric conversion region 15 and enters an on-chip lens array 19. In order to improve the utilization efficiency of light, it is desirable to use the on-chip lens array 19 to scatter the diffraction light. Hence, it is desirable to form an end face of the on-chip lens array 19 on the photoelectric conversion region 15 side in a recessed and protruding shape as depicted in FIG. 5 to thereby improve the scattering property. A scattering member 19a having such a recessed and protruding shape as just described also plays a role of preventing light entering the on-chip lens array 19 from the outside of the image capturing apparatus 1 from being reflected by the on-chip lens array 19.

In a case where image capturing object light entering the photoelectric conversion region 15 includes high luminance light source light, there is a possibility that a flare by diffraction light may be reflected on the outer side of the range of the high luminance light source light reflected in a captured image, and such a flare makes a cause of picture quality deterioration. Thus, in the present embodiment, the range of diffraction light is hidden within the range of the high luminance light source light to be reflected on the captured image, to thereby suppress the flare.

FIG. 7 is a view depicting a positional relation between the photoelectric conversion region 15 and the cover glass 12. It is to be noted that the cover glass 12 may otherwise be the on-chip lens array 19.

In FIG. 7, where the distance between the cover glass 12 and the photoelectric conversion region 15 is represented by h, the angle of diffraction light when the light source light is diffracted by the light incidence face of the photoelectric conversion region 15 is represented by θ, and the distance from the incidence position of the light source light on the photoelectric conversion region 15 to a position at which the diffraction light enters the photoelectric conversion region 15 again after being reflected by the cover glass 12 is represented by x, the following expression (6) is obtained.

$$x = 2 h \times tan θ \qquad ( 6 )$$

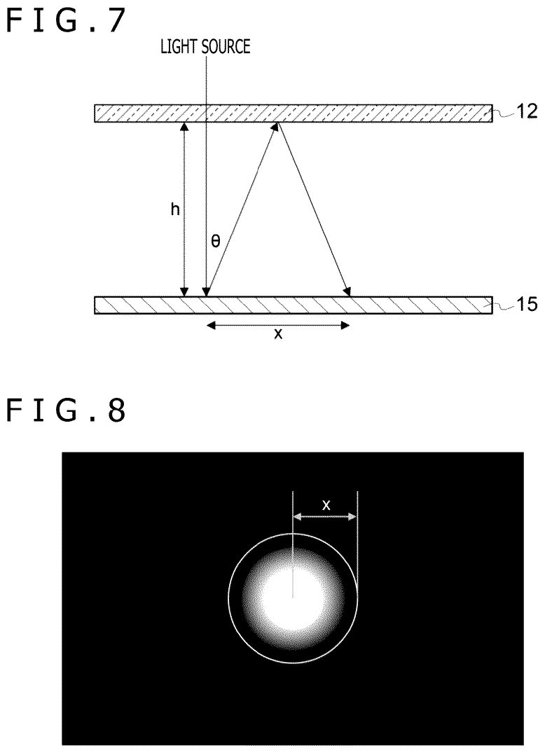

FIG. 8 is a view depicting an image capturing range of high luminance light source light. The distance x in FIG. 7 is the image capturing range of the high luminance light source light.

Meanwhile, where the pattern period of the photoelectric conversion region 15 is represented by d, the wavelength of incidence light is represented by λ, and the diffraction order number is represented by m, the following expression (7) is obtained. The pattern period d is a period of the periodic structure of the photoelectric conversion region 15 described hereinabove.

$$m λ / d = sin θ \qquad ( 7 )$$

From the expression (6) and the expression (7), when the pattern period d satisfies the relation of the expression 8 given below, the flare is hidden within the range of the light source light.

$$\begin{matrix}[ Math . 2 ] & \\ d > \frac{λ}{sin ( {tan}^{- 1} ( \frac{x}{2 h} ) )} & ( 8 )\end{matrix}$$

As can be recognized from the expression (8), the pattern period d depends upon the wavelength λ of the incidence light, the distance h from the photoelectric conversion region 15 to the cover glass 12, and the distance x from the light source.

The pattern period d in a case where the light controlling region 16 is arranged on the face side opposite to the light incidence face of the photoelectric conversion region 15 as depicted in FIG. 5 and light is diffracted by the light controlling region 16 is the period of the unit structural body 21 of the light controlling region 16. The unit structural body 21 includes a plurality of meta structural bodies 22 as depicted, for example, in FIG. 6, and the pattern period d is determined by two or more meta structural bodies 22 that are arranged in the X direction and the Y direction and have optical characteristics different from each other.

In such a manner, by determining the pattern period d in such a manner as to satisfy the expression (8), it is possible to hide the flare range by diffraction light within the range of light source light that is reflected in a captured image, and the flare becomes less outstanding.

Although, in the image capturing apparatus 1 depicted in FIG. 5, the light controlling region 16 is provided on the face side opposite to the light incidence face of the photoelectric conversion region 15, it is also possible to provide the light controlling region 16 otherwise on the light incidence face side of the photoelectric conversion region 15.

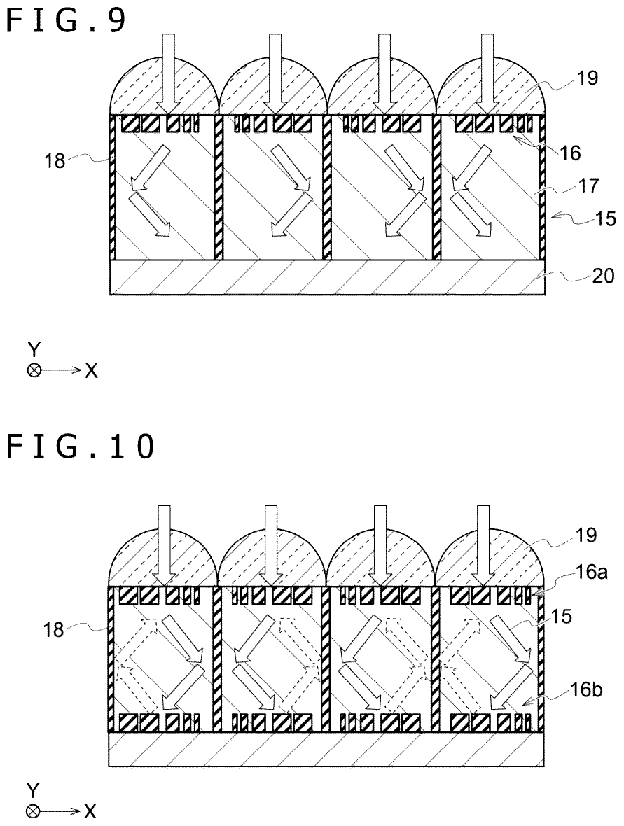

FIG. 9 is a cross sectional view of the image capturing apparatus 1 according to a first modification to that of FIG. 5 in a lamination direction. The image capturing apparatus 1 of FIG. 9 is different from the image capturing apparatus 1 of FIG. 5 in that the light controlling region 16 is arranged on the light incidence face side of the photoelectric conversion region 15.

The light controlling region 16 of FIG. 9 has a plurality of unit structural bodies 21, for example, of the same structure similarly to the light controlling region 16 of FIG. 5. Each of the unit structural bodies 21 has a plurality of meta structural bodies 22 as depicted, for example, in FIG. 6. The plurality of meta structural bodies 22 include two or more meta structural bodies 22 having optical characteristics different from each other.

Incidence light transmitted through the on-chip lens array 19 in the image capturing apparatus 1 of FIG. 9 enters the meta structural bodies 22 in the light controlling region 16. Each meta structural body 22 changes an optical characteristic of the incident light. More particularly, each meta structural body 22 makes the optical path length of the incidence light longer. Consequently, at least part of the light transmitted through the light controlling region 16 has an increased optical path length when the light propagates in the photoelectric conversion region 15, resulting in improvement of the quantum efficiency Qe.

Further, since the light controlling region 16 has a periodic structure having one period equal to the size of the unit structural body 21, it can reduce the intensity of diffraction light diffracted by the light controlling region 16, and the flare can be suppressed thereby.

FIG. 10 is a cross sectional view of an image capturing apparatus 1 according to a second modification to that of FIG. 5 in a lamination direction. The image capturing apparatus 1 of FIG. 10 includes a first light controlling region 16a provided on the light incidence face side of the photoelectric conversion region 15 and a second light controlling region 16b provided on the opposite face side. The first light controlling region 16a and the second light controlling region 16b include a plurality of unit structural bodies 21, for example, of the same structure, similarly to the light controlling regions 16 in FIGS. 5 and 9. Each of the unit structural bodies 21 includes a plurality of meta structural bodies 22 as depicted, for example, in FIG. 6. It is to be noted that the meta structural body 22 provided on the unit structural body 21 of the first light controlling region 16a and the meta structural body 22 provided on the unit structural body 21 of the second light controlling region 16b may be different in shape, size, or the like from each other.

In the image capturing apparatus 1 of FIG. 10, diffraction light propagating in the photoelectric conversion region 15 and diffracted by the second light controlling region 16b can be diffracted by the first light controlling region 16a, and the diffraction light can be confined to the photoelectric conversion region 15, so that the quantum efficiency Qe can be improved.

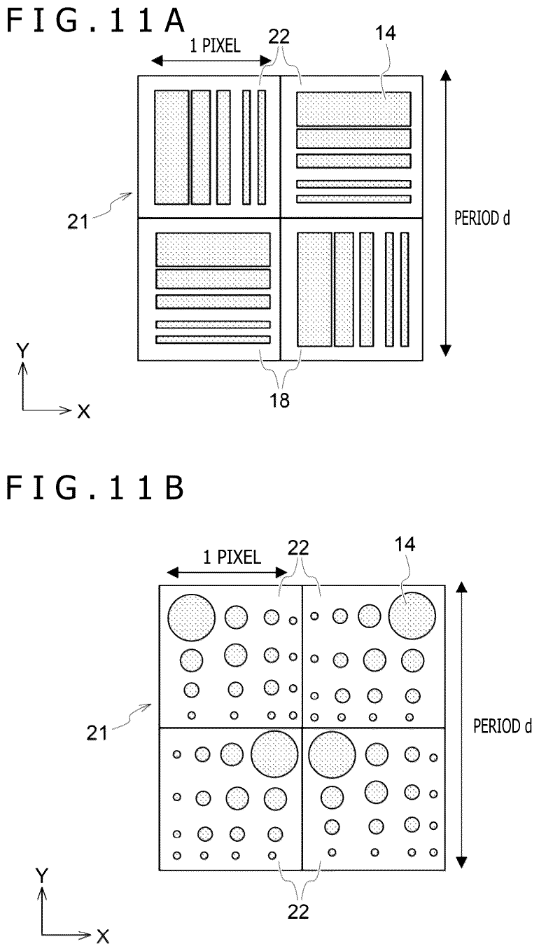

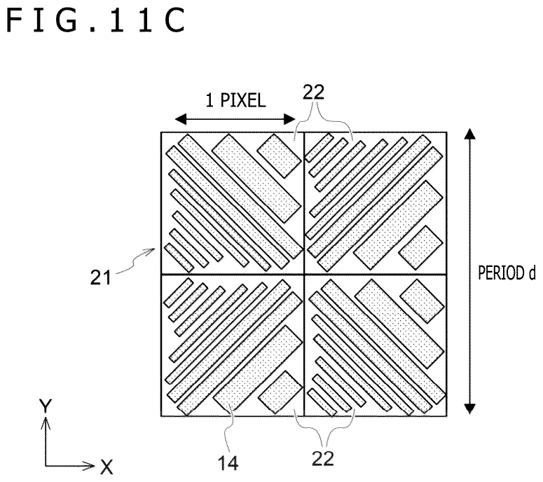

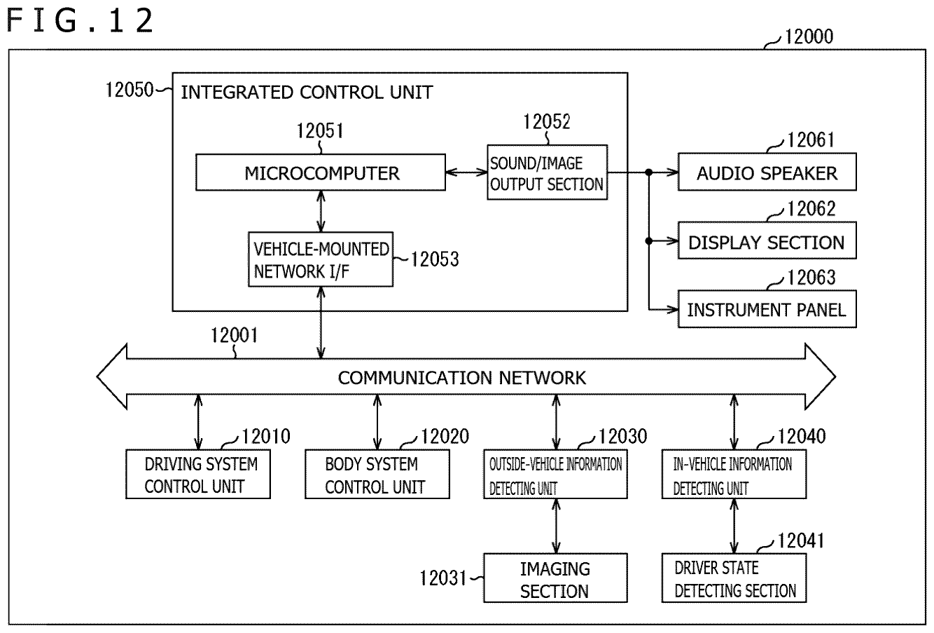

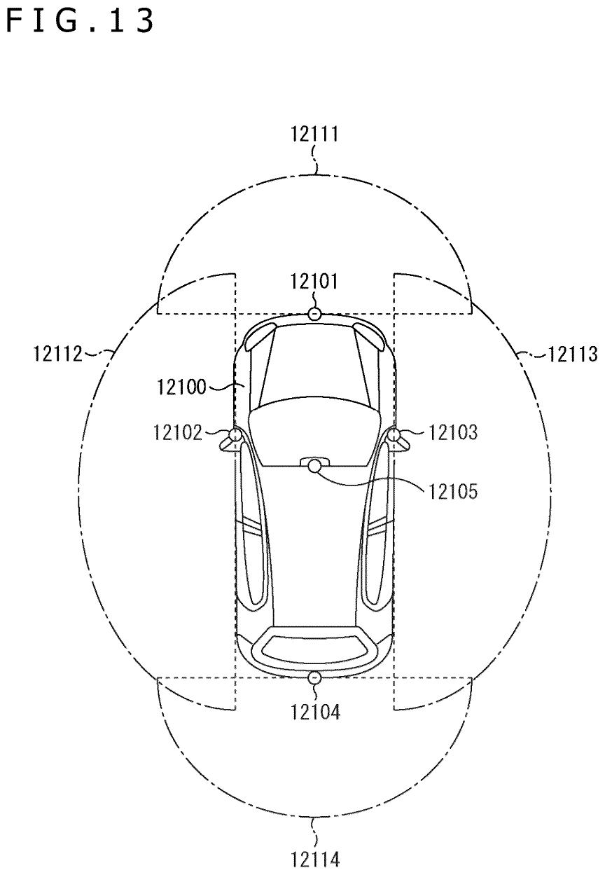

The shape of the unit structural body 21 in the light controlling region 16 is not restricted to that depicted in FIG. 6. FIGS. 11A, 11B, and 11C are cross sectional views of unit structural bodies 21 having shapes different from that in FIG. 6. All of the unit structural bodies 21 in FIGS. 11A, 11B, and 11C include two meta structural bodies 22 in the X direction and two meta structural bodies 22 in the Y direction.

The meta structural body 22 of FIG. 11A has a plurality of microstructural bodies 14 having a cross section of a rectangular shape and short sides having widths different from one another. Each of the microstructural bodies 14 extends in the depthwise direction of the light controlling region 16 and has a shape of a rectangular parallelepiped. Of the four meta structural bodies 22 of FIG. 11A, two meta structural bodies 22 arranged in a diagonal direction have microstructural bodies 14 of the same shape. Meanwhile, in two meta structural bodies 22 adjacent in the X direction and the Y direction to each other, the orientations of the microstructural bodies 14 are different by 90 degrees from each other.

The meta structural body 22 of FIG. 11B includes a plurality of microstructural bodies 14 having a circular cross section and having diameters different from each other. Each of the microstructural bodies 14 extends in the depthwise direction of the light controlling region 16 and has a cylindrical shape. Of the four meta structural bodies 22 of FIG. 11B, two meta structural bodies 22 arranged in a diagonal direction have microstructural bodies 14 of the same shape. Meanwhile, in two meta structural bodies 22 that are adjacent in the X direction and the Y direction to each other, the microstructural bodies 14 having diameters different from each other are reverse in the direction in which they are lined up.

The meta structural body 22 of FIG. 11C has a plurality of microstructural bodies 14 having a cross section of a rectangular shape having long sides and short sizes that have widths different from each other. The long sides of each microstructural body 14 are arranged substantially in parallel to a diagonal direction of the meta structural body 22 of the rectangular shape. Each microstructural body 14 extends in the depthwise direction of the light controlling region 16 and has a shape of a parallelepiped. Of the four meta structural bodies 22 of FIG. 11C, two meta structural bodies 22 arranged in a diagonal direction have microstructural bodies 14 of the same shape. Meanwhile, in two meta structural bodies 22 adjacent in the X direction and the Y direction to each other, the orientations of the microstructural bodies 14 are different by 90 degrees from each other.

The light controlling region 16 in the image capturing apparatus 1 according to the present disclosure may include the unit structural bodies 21 depicted in any of FIGS. 6 and 11A to 11C or may include unit structural bodies 21 of a shape different from those of them.

Although FIGS. 6 and 11A to 11C depict examples of the unit structural body 21 having 2×2 meta structural bodies 22, the light controlling region 16 may be configured otherwise such that unit structural bodies 21 having n×n (n is any integer equal to or greater than 2) meta structural bodies 22 are arranged in two-dimensional directions. In this case, the light controlling region 16 has a periodic structure having a size equal to the size of the n meta structural bodies.

In such a manner, in the present embodiment, in order to suppress a flare by diffraction light diffracted by the photoelectric conversion region 15, the light controlling region 16 is provided on at least one of the light incidence face side and the opposite face side of the photoelectric conversion region 15 to increase the order number of diffraction light and decrease the light intensity of the diffraction light, and therefore, the flare can be suppressed. Further, since the light controlling region 16 is adjusted such that a flare by diffraction light is hidden within the range of high luminance light source light to be reflected in an image captured by the photoelectric conversion region 15, a flare is not reflected on the outer side of the high luminance light source light, and the picture quality of the captured image can be improved.

Since the light controlling region 16 according to the present embodiment has a plurality of unit structural bodies 21, for example, of a same structure and each unit structural body 21 has a plurality of meta structural bodies 22, by adjusting the shape, direction, size, or the like of the microstructural body 14 in the meta structural body 22, it is possible to provide the light controlling region 16 with a periodic structure having one period equal to the size of the unit structural body 21. Accordingly, it is possible to decrease the light intensity of diffraction light while increasing the order number of diffraction light diffracted by the light controlling region 16, so that the flare can be suppressed.

### <Example of Application to Mobile Body>

The technology according to the present disclosure (present technology) can be applied to various products. For example, the technology according to the present disclosure may be implemented as an apparatus to be incorporated in any of various kinds of mobile bodies such as automobiles, electric automobiles, hybrid electric automobiles, motorcycles, bicycles, personal mobilities, airplanes, drones, ships, and robots.

FIG. 18 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 18, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 18, an audio speaker 12061, a display section 12062, and an instrument panel 12063 are illustrated as the output device. The display section 12062 may, for example, include at least one of an on-board display and a head-up display.

FIG. 19 is a diagram depicting an example of the installation position of the imaging section 12031.

In FIG. 19, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 19 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Note that the present technology can also take the following configurations.

(1)

An image capturing apparatus including:
a photoelectric conversion region having a photoelectric conversion portion for each pixel; and
a light controlling region laminated on the photoelectric conversion region and configured to convert an optical characteristic of light incident thereon, in which
the light controlling region has a plurality of unit structural bodies,
each of the plurality of unit structural bodies has a plurality of meta structural bodies, and
the plurality of meta structural bodies include two or more meta structural bodies whose optical characteristics are different from each other.
   (2)

The image capturing apparatus according to (1), in which the light controlling region increases an optical path length of IR (Infrared Ray) light incident thereon.

(3)

The image capturing apparatus according to (1) or (2), in which each of the plurality of meta structural bodies is provided in a corresponding relation with a pixel.

(4)

The image capturing apparatus according to any one of (1) through (3), in which the plurality of unit structural bodies have the same structure, and
each of the plurality of unit structural bodies has the meta structural bodies arranged in plural number in each of two-dimensional directions.
   (5)

The image capturing apparatus according to any one of (1) through (4), in which each of the plurality of meta structural bodies in the unit structural body includes a plurality of types of microstructural bodies that are different from each other in at least one of width, size, and shape, and
each of the plurality of meta structural bodies converts an optical characteristic of light incident on a corresponding one of the microstructural bodies according to at least one of the width, size, and shape of the plurality of types of microstructural bodies.
   (6)

The image capturing apparatus according to (5), in which the unit structural body has two or more of the meta structural bodies arranged in a first direction and two or more of the meta structural bodies arranged in a second direction intersecting with the first direction,
two of the meta structural bodies that are adjacent to each other in the first direction are different from each other in orientation of the microstructural bodies, and
two of the meta structural bodies that are adjacent to each other in the second direction are different from each other in orientation of the microstructural bodies.
   (7)

The image capturing apparatus according to (6), in which the plurality of meta structural bodies in the unit structural body have the microstructural bodies that are different from each other in orientation.

(8)

The image capturing apparatus according to (7), in which the plurality of meta structural bodies in the unit structural body have the microstructural bodies that are different in orientation by 90 degrees from each other, and
the plurality of unit structural bodies have two of the meta structural bodies arranged adjacent to each other in the first direction and two of the meta structural bodies arranged adjacent to each other in the second direction.
   (9)

The image capturing apparatus according to claim 6, in which each of the plurality of meta structural bodies in the unit structural body has the plurality of types of the microstructural bodies having circular transverse sections having diameters different from each other.

(10)

The image capturing apparatus according to (6), in which two of the meta structural bodies that are arranged in a diagonal direction among the plurality of meta structural bodies in the unit structural body have the microstructural bodies of a same orientation, and
the plurality of unit structural bodies have two of the meta structural bodies that are arranged adjacent to each other in the first direction but are different in orientation from each other, and two of the meta structural bodies that are arranged adjacent to each other in the second direction but are different in orientation from each other.
   (11)

The image capturing apparatus according to any one of (6) through (10), in which each of the plurality of unit structural bodies includes n×n (n is any integer equal to or greater than 2) of the meta structural bodies arranged n by n in two-dimensional directions, and
the light controlling region has a periodic structure having a size equal to a size of the n meta structural bodies.
   (12)

The image capturing apparatus according to (11), in which the light controlling region generates diffraction light according to the periodic structure from incident light and allows the diffraction light to propagate inside the light controlling region.

(13)

The image capturing apparatus according to (12), in which the light controlling region adjusts the plurality of unit structural bodies such that an incidence range of the diffraction light is included in an incidence range of light from a light source that is to enter the photoelectric conversion region.

(14)

The image capturing apparatus according to claim 13, further including:
a light transmission member arranged on a light incidence side with respect to the photoelectric conversion region and configured to re-reflect light reflected by the photoelectric conversion region, in which
the unit structural body satisfies, where a period of the unit structural body is d, a wavelength of the incidence light is λ, a distance from the light transmission member to the photoelectric conversion region is h, and a range of light from the light source is x, expression (9):

$$\begin{matrix}[ Math . 3 ] & \\ d > \frac{λ}{sin ( {tan}^{- 1} ( \frac{x}{2 h} ) )} & ( 9 )\end{matrix}$$

(15)

The image capturing apparatus according to claim 14, in which the light transmission member has an on-chip lens array that condenses incident light.

(16)

The image capturing apparatus according to any one of (1) through (15), in which the light controlling region is arranged on a face side opposite to a light incidence face of the photoelectric conversion region, and diffracts light transmitted through the photoelectric conversion region and incident on the light controlling region, to allow the diffraction light to propagate in the photoelectric conversion region.

(17)

The image capturing apparatus according to (16), further including:
a scattering member arranged along the light incidence face of the photoelectric conversion region, in which
the scattering member scatters the light diffracted by the light controlling region and propagating in the photoelectric conversion region.
   (18)

The image capturing apparatus according to any one of (1) through (17), in which the light controlling region is arranged on a light incidence face side of the photoelectric conversion region and configured to increase an optical path length of the incident light by the plurality of unit structural bodies in the light controlling region and thereby allow the incident light to propagate along the optical path in the photoelectric conversion region.

(19)

The image capturing apparatus according to any one of (1) through (16), in which the light controlling region has
a first light controlling region arranged on a light incidence face side of the photoelectric conversion region, and
a second light controlling region arranged on a face side opposite to the light incidence face of the photoelectric conversion region, and
the first light controlling region and the second light controlling region diffract light propagating in the photoelectric conversion region and incident thereon and allow the diffracted light to propagate in the photoelectric conversion region.
   (20)

Electronic equipment including:
an image capturing apparatus that outputs a pixel signal that is imaged; and
a signal processing section that performs signal processing for the pixel signal, in which
the image capturing apparatus includes
   a photoelectric conversion region having a photoelectric conversion portion for each pixel, and
   a light controlling region laminated on the photoelectric conversion region and configured to convert an optical characteristic of light incident thereon,
the light controlling region is arranged along a light incidence face and has a plurality of unit structural bodies, and
each of the plurality of unit structural bodies has a plurality of meta structural bodies whose optical characteristics are different from each other.

The mode of the present disclosure is not restricted to the individual embodiments described hereinabove and includes various modifications those skilled in the art may arrive at, and also the advantageous effects of the present disclosure are not restricted to the substance described hereinabove. In particular, it is possible to make various additions, alterations, and partial deletions without departing from the conceptual ideas and scopes of the present disclosure derived from the substance defined in the claims and equivalents to them.

### REFERENCE SIGNS LIST

1: Image capturing apparatus
2: Pixel array section
3: Vertical driving circuit
4: Column signal processing circuit
5: Horizontal driving circuit
6: Outputting circuit
7: Control circuit
10: Pixel
11: Image capturing sensor
11: Sensor
12: Cover glass
13: Module lens
14: Microstructural body
15: Photoelectric conversion region
16: Light controlling region
16a: First light controlling region
16b: Second light controlling region
17: Photoelectric conversion portion
18: Light shielding member
19: On-chip lens array
19a: Scattering member
20: Wiring region
21: Unit structural body
22: Meta structural body
100: Image capturing apparatus

1. An image capturing apparatus comprising:
a photoelectric conversion region having a photoelectric conversion portion for each pixel; and
a light controlling region laminated on the photoelectric conversion region and configured to convert an optical characteristic of light incident thereon, wherein
the light controlling region has a plurality of unit structural bodies,
each of the plurality of unit structural bodies has a plurality of meta structural bodies, and
the plurality of meta structural bodies include two or more meta structural bodies whose optical characteristics are different from each other.

2. The image capturing apparatus according to claim 1, wherein the light controlling region increases an optical path length of IR (Infrared Ray) light incident thereon.

3. The image capturing apparatus according to claim 1, wherein each of the plurality of meta structural bodies is provided in a corresponding relation with a pixel.

4. The image capturing apparatus according to claim 1, wherein the plurality of unit structural bodies have a same structure, and
each of the plurality of unit structural bodies has the meta structural bodies arranged in plural number in each of two-dimensional directions.

5. The image capturing apparatus according to claim 1, wherein each of the plurality of meta structural bodies in the unit structural body includes a plurality of types of microstructural bodies that are different from each other in at least one of width, size, and shape, and
each of the plurality of meta structural bodies converts an optical characteristic of light incident on a corresponding one of the microstructural bodies according to at least one of the width, size, and shape of the plurality of types of microstructural bodies.

6. The image capturing apparatus according to claim 5, wherein the unit structural body has two or more of the meta structural bodies arranged in a first direction and two or more of the meta structural bodies arranged in a second direction intersecting with the first direction,
two of the meta structural bodies that are adjacent to each other in the first direction are different from each other in orientation of the microstructural bodies, and
two of the meta structural bodies that are adjacent to each other in the second direction are different from each other in orientation of the microstructural bodies.

7. The image capturing apparatus according to claim 6, wherein the plurality of meta structural bodies in the unit structural body have the microstructural bodies that are different from each other in orientation.

8. The image capturing apparatus according to claim 7, wherein the plurality of meta structural bodies in the unit structural body have the microstructural bodies that are different in orientation by 90 degrees from each other, and
the plurality of unit structural bodies have two of the meta structural bodies arranged adjacent to each other in the first direction and two of the meta structural bodies arranged adjacent to each other in the second direction.

9. The image capturing apparatus according to claim 6, wherein each of the plurality of meta structural bodies in the unit structural body has the plurality of types of the microstructural bodies having circular transverse sections having diameters different from each other.

10. The image capturing apparatus according to claim 6, wherein two of the meta structural bodies that are arranged in a diagonal direction among the plurality of meta structural bodies in the unit structural body have the microstructural bodies of a same orientation, and
the plurality of unit structural bodies have two of the meta structural bodies that are arranged adjacent to each other in the first direction but are different in orientation from each other, and two of the meta structural bodies that are arranged adjacent to each other in the second direction but are different in orientation from each other.

11. The image capturing apparatus according to claim 6, wherein each of the plurality of unit structural bodies includes n×n (n is any integer equal to or greater than 2) of the meta structural bodies arranged n by n in two-dimensional directions, and
the light controlling region has a periodic structure having a size equal to a size of the n meta structural bodies.

12. The image capturing apparatus according to claim 11, wherein the light controlling region generates diffraction light according to the periodic structure from incident light and allows the diffraction light to propagate inside the light controlling region.

13. The image capturing apparatus according to claim 12, wherein the light controlling region adjusts the plurality of unit structural bodies such that an incidence range of the diffraction light is included in an incidence range of light from a light source that is to enter the photoelectric conversion region.

14. The image capturing apparatus according to claim 13, further comprising:
a light transmission member arranged on a light incidence side with respect to the photoelectric conversion region and configured to re-reflect light reflected by the photoelectric conversion region, wherein
the unit structural body satisfies, where a period of the unit structural body is d, a wavelength of the incidence light is λ, a distance from the light transmission member to the photoelectric conversion region is h, and a range of light from the light source is x, expression (1):
$$\begin{matrix}[ Math . 1 ] & \\ d > \frac{λ}{sin ( {tan}^{- 1} ( \frac{x}{2 h} ) )} & ( 1 )\end{matrix}$$

15. The image capturing apparatus according to claim 14, wherein the light transmission member has an on-chip lens array that condenses incident light.

16. The image capturing apparatus according to claim 1, wherein the light controlling region is arranged on a face side opposite to a light incidence face of the photoelectric conversion region, and diffracts light transmitted through the photoelectric conversion region and incident on the light controlling region, to allow the diffraction light to propagate in the photoelectric conversion region.

17. The image capturing apparatus according to claim 16, further comprising:
a scattering member arranged along the light incidence face of the photoelectric conversion region, wherein
the scattering member scatters the light diffracted by the light controlling region and propagating in the photoelectric conversion region.

18. The image capturing apparatus according to claim 1, wherein the light controlling region is arranged on a light incidence face side of the photoelectric conversion region and configured to increase an optical path length of the incident light by the plurality of unit structural bodies in the light controlling region and thereby allow the incident light to propagate along the optical path in the photoelectric conversion region.

19. The image capturing apparatus according to claim 1, wherein the light controlling region has
a first light controlling region arranged on a light incidence face side of the photoelectric conversion region, and
a second light controlling region arranged on a face side opposite to the light incidence face of the photoelectric conversion region, and
the first light controlling region and the second light controlling region diffract light propagating in the photoelectric conversion region and incident thereon and allow the diffracted light to propagate in the photoelectric conversion region.

20. Electronic equipment comprising:
an image capturing apparatus that outputs a pixel signal that is imaged; and
a signal processing section that performs signal processing for the pixel signal, wherein
the image capturing apparatus includes
a photoelectric conversion region having a photoelectric conversion portion for each pixel, and
a light controlling region laminated on the photoelectric conversion region and configured to convert an optical characteristic of light incident thereon,
the light controlling region is arranged along a light incidence face and has a plurality of unit structural bodies, and
each of the plurality of unit structural bodies has a plurality of meta structural bodies whose optical characteristics are different from each other.
